(19) United States
(12) Patent Application Publication
(10) Pub. No.: US 2025/0203880 A1
(43) Pub. Date: Jun. 19, 2025

(54) SEMICONDUCTOR DEVICE INCLUDING A MEMORY CELL HAVING A CARRIER TUNNELING LAYER

(71) Applicant: SK hynix Inc., Icheon-si (KR)

(72) Inventors: Jeong Myeong KIM, Icheon-si (KR); Cha Deok DONG, Icheon-si (KR); Keo Rock CHOI, Icheon-si (KR)

(21) Appl. No.: 18/916,542

(22) Filed: Oct. 15, 2024

(30) Foreign Application Priority Data
Dec. 15, 2023 (KR) 10-2023-0183395

(51) Int. Cl. H10B 63/00; H10N 70/00

(52) U.S. Cl. CPC H10B 63/80; H10N 70/023; H10N 70/026; H10N 70/841; H10N 70/8833; H10N 70/8845

(57) ABSTRACT

A semiconductor device includes a lower interconnection line; a memory cell structure over the lower interconnection line; and an upper interconnection line over the memory cell structure. The memory cell structure includes a first electrode; a selection element over the first electrode; a first carrier tunneling layer over the selection element layer; a second electrode over the first carrier tunneling layer; a memory element layer over the second electrode; and a third electrode over the memory element layer. The first carrier tunneling layer includes an insulating layer doped with at least one pentavalent element.

### PRIORITY CLAIM AND CROSS-REFERENCE TO RELATED APPLICATION

This patent document claims the priority and benefits of Korean Patent Application No. 10-2023-0183395 filed on Dec. 15, 2023, which is incorporated herein by reference in its entirety.

### TECHNICAL FIELD

Embodiments of the disclosed technology relate to a cross-point type semiconductor device having a memory cell.

### BACKGROUND

Recently, various electronic devices such as miniaturized, lower-power, higher-performance computers and portable communication devices require semiconductor devices that can store data. Semiconductor memory devices that store data using the property of switching between different resistance states and/or magnetic states depending on the voltage or current applied thereto are being developed.

### SUMMARY

In an embodiment of the disclosure, a semiconductor device includes a lower interconnection line; a memory cell structure over the lower interconnection line; and an upper interconnection line over the memory cell structure. The memory cell structure includes a first electrode; a selection element layer disposed over the first electrode; a first carrier tunneling layer disposed over the selection element layer; a second electrode over the first carrier tunneling layer; a memory element layer over the second electrode; and a third electrode over the memory element layer. The first carrier tunneling layer includes an insulating layer doped with at least one pentavalent element.

In an embodiment of the disclosure, a semiconductor device includes a lower interconnection line; a first electrode over the lower interconnection line; a selection element layer over the first electrode; a second electrode over the selection element layer; a memory element layer disposed over the second electrode; a third electrode over the memory element layer; an upper interconnection line on the third electrode; and a carrier tunneling layer disposed between the first electrode and the selection element layer or between the selection element layer and the second electrode. The second electrode includes a carbon-based material layer. The carrier tunneling layer includes an insulating layer doped with at least one pentavalent element.

In an embodiment of the disclosure, a method of forming a semiconductor device includes forming a first electrode material layer, forming, over the first electrode material layer, a selection element layer material layer to be used as a selection element layer configured to exhibit different electrical conducting characteristics in response to an applied voltage or current with respect to a threshold voltage or current, forming, over the selection element material layer, an upper carrier tunneling material layer to be used as an upper carrier tunneling layer configured to allow tunneling of carriers in a first state and block a leakage current in a second state, forming, over the upper carrier tunneling material layer, a second electrode material layer to be used as a second electrode, forming, over the second electrode material layer, a memory element layer material layer to be used as a memory element layer configured to store data, forming, over the memory element material layer, a third electrode material layer to be used as a third electrode, and performing a patterning process on the third electrode material layer, the memory element material layer, the second electrode material layer, the upper carrier tunneling material layer, the selection element material layer, and the first electrode material layer to form a memory cell structure including the first electrode, the selection element layer, the upper carrier tunneling layer, the second electrode, the memory element layer, and the third electrode. Forming the upper carrier tunneling layer includes forming a silicon-based insulating material layer, and doping at least one of arsenic, phosphorus, or antimony into the silicon-based insulating material layer by performing an ion doping process.

In an embodiment of the disclosure, a method for forming a semiconductor device includes forming a lower interconnection line, forming a first electrode over the lower interconnection line, forming, over the first electrode, a selection element layer configured to exhibit different electrical conducting characteristics in response to an applied voltage or current with respect to a threshold voltage or current, forming a second electrode over the selection element layer, forming, over the second electrode, a memory element layer configured to store data, forming a third electrode over the memory element layer, forming an upper interconnection line over the third electrode, and forming, between the first electrode and the selection element layer or between the selection element layer and the second electrode, a carrier tunneling layer configured to allow tunneling of carriers in a first state and block a leakage current in a second state. Forming the carrier tunneling layer includes forming an insulating layer by performing a deposition process, and doping arsenic into the insulating layer by performing an ion doping process.

### BRIEF DESCRIPTION OF THE DRAWINGS

FIG. 1 is a perspective view schematically illustrating a cross-point cell array 100 of a semiconductor memory device.

FIGS. 2A to 2C are longitudinal cross-sectional views taken along the line I-I′ of FIG. 1.

FIG. 3 is a diagram illustrating a memory element layer.

FIGS. 4A to 4D, FIGS. 5A to 5D, FIGS. 6A to 6D, FIGS. 7A and 7B, FIGS. 8A and 8B, and FIGS. 9A to 9C are longitudinal cross-sectional views taken along the line I-I′ of FIG. 1 to describe methods of forming memory cell structures.

### DETAILED DESCRIPTION

Hereinafter, various embodiments of the disclosure will be described in detail with reference to the accompanying drawings.

The drawings are not necessarily drawn to scale. In some instances, proportions of at least some structures in the drawings may have been exaggerated in order to clearly illustrate certain features of the described embodiments. In presenting a specific example in a drawing or description having two or more layers in a multi-layer structure, the relative positioning relationship of such layers or the sequence of arranging the layers as shown reflects a particular implementation for the described or illustrated example and a different relative positioning relationship or sequence of arranging the layers may be possible. In addition, a described or illustrated example of a multi-layer structure might not reflect all layers present in that particular multilayer structure (e.g., one or more additional layers may be present between two illustrated layers). As a specific example, when a first layer in a described or illustrated multi-layer structure is referred to as being “on” or “over” a second layer or “on” or “over” a substrate, the first layer may be directly formed on the second layer or the substrate but may also represent a structure where one or more other intermediate layers may exist between the first layer and the second layer or the substrate.

The disclosed technology can be implemented in some embodiments to provide a cross-point type semiconductor device including a memory cell that includes a carrier tunneling layer configured to perform a leakage current blocking function or a switch function for allowing tunneling of charge carriers. For example, the carrier tunneling layer may be configured to allow tunneling of charge carriers in an “on” state and to block a leakage current in an “off” state.

In addition, the disclosed technology can be implemented in some embodiments to provide a method of manufacturing a cross-point type semiconductor device including a memory cell having a carrier tunneling layer configured to perform a leakage current blocking function or a switch function for allowing tunneling of carriers.

Furthermore, the disclosed technology can be implemented in some embodiments to provide a cross-point type semiconductor device including a memory cell that includes an ion chemical reaction element and/or an ion-doped selection element layer.

The disclosed technology can also be implemented in some embodiments to provide a method of manufacturing a cross-point type semiconductor device including a memory cell that includes an ion chemical reaction element and/or an ion-doped selection element layer.

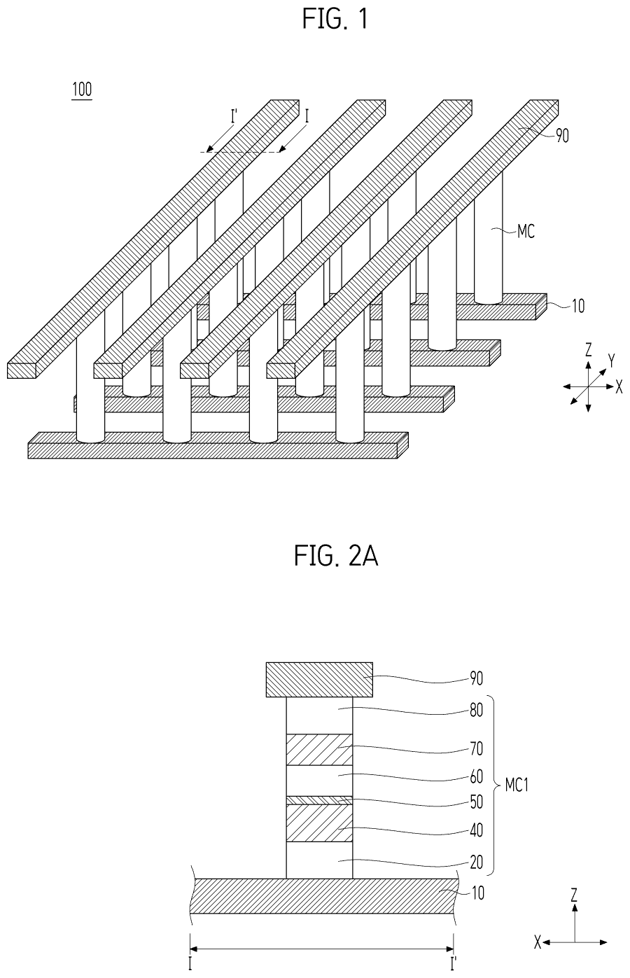

FIG. 1 is a perspective view schematically illustrating a cross-point cell array 100 of a semiconductor memory device based on an embodiment of the disclosed technology. Referring to FIG. 1, a cross-point cell array 100 of a semiconductor memory device based on an embodiment of the disclosed technology may include lower interconnection lines 10, upper interconnection lines 90, and memory cell structures MC. In some implementations, the term “interconnection line” can be used to indicate a transmission line that can be used to transmit electrical signals between different regions in the semiconductor memory device. The lower interconnection lines 10 may extend in parallel to each other in a first horizontal direction X. The upper interconnection lines 90 may extend in parallel to each other in a second horizontal direction Y. The first horizontal direction X and the second horizontal direction Y may be perpendicular to each other. The memory cell structures MC may be disposed at intersections between the lower interconnection lines 10 and the upper interconnection lines 90, respectively. Each of the memory cell structures MC may have a cylindrical pillar shape.

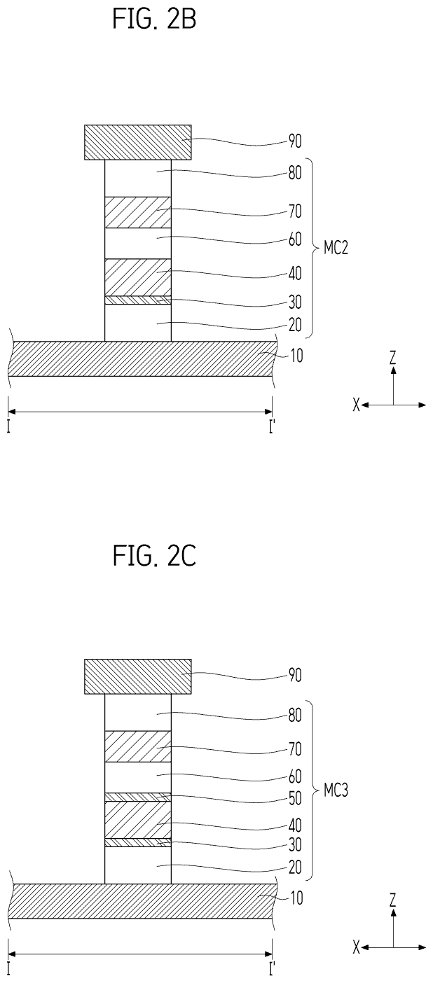

FIGS. 2A to 2C are longitudinal cross-sectional views taken along the line I-I′ of FIG. 1. Referring to FIGS. 2A to 2C, a semiconductor memory devices based on embodiments of the disclosed technology may include lower interconnection lines 10, upper interconnection lines 90, and memory cell structures MC1-MC3, respectively. The memory cell structures MC1 to MC3 disposed between the lower interconnection lines 10 and the upper interconnection lines 90, respectively. Each of the lower interconnection lines 10 may be disposed on a substrate and/or a lower insulating layer. As described above, each of the lower interconnection lines 10 may have a line shape extending in the first horizontal direction X. The lower interconnection line 10 may include a conductor, e.g., a metal, a metal silicide, a metal compound, or a metal alloy. For example, the lower interconnection line 10 may include at least one of tungsten (W), titanium (Ti), tantalum (Ta), platinum (Pt), aluminum (Al), copper (Cu), zinc (Zn), nickel (Ni), cobalt (Co), lead (Pd), chromium (Cr), tungsten nitride (WN), tungsten silicide (WSi), titanium silicide (TiSi), titanium nitride (TiN), titanium silicon nitride (TiSiN), titanium aluminum nitride (TiAlN), tantalum nitride (TaN), tantalum silicon nitride (TaSiN), tantalum aluminum nitride (TaAlN), titanium aluminum (TiAl), or and combinations thereof. The upper interconnection line 90 may be disposed on the memory cell structure MC. Referring to FIG. 1, each of the upper interconnection lines 90 may have a line shape extending in the second horizontal direction Y. The upper interconnection line 90 may include a conductor, e.g., a metal, a metal silicide, a metal compound, or a metal alloy. For example, the upper interconnection line 90 may include at least one of the materials referred for the lower interconnection line 10.

Referring to FIG. 2A, a memory cell structure MC1 of a semiconductor memory element layer based on an embodiment of the disclosed technology may include a first electrode (lower electrode) 20, a selection element layer 40, an upper carrier tunneling layer 50, a second electrode (middle electrode) 60, a memory element layer 70, and a third electrode (upper electrode) 80 stacked in a vertical direction Z. The memory cell structure MC1 may be disposed between a lower interconnection line 10 and an upper interconnection line 90. The lower electrode 20, the selection element layer 40, the upper carrier tunneling layer 50, the middle electrode 60, the memory element layer 70, and the upper electrode 80 may have one of a pillar shape or a pad shape, respectively.

The lower electrode 20 may be directly disposed on the lower interconnection line 10. The lower electrode 20 may receive a voltage or current from the lower interconnection line 10 and transmit or provide the voltage or current to the selection element layer 40. The lower electrode 20 may include a conductor, e.g., a metal, a metal silicide, a metal compound, or a metal alloy. For example, the lower electrode 20 may include at least one of tungsten (W), titanium (Ti), tantalum (Ta), platinum (Pt), aluminum (Al), copper (Cu), zinc (Zn), nickel (Ni), cobalt (Co), chromium (Cr), tungsten nitride (WN), tungsten silicide (WSi), titanium silicide (TiSi), titanium nitride (TiN), titanium silicon nitride (TiSiN), titanium aluminum nitride (TiAlN), tantalum nitride (TaN), tantalum silicon nitride (TaSiN), tantalum aluminum nitride (TaAlN), tantalum aluminum nitride (TaAlN), titanium aluminum (TiAl), or combinations thereof.

The selection element layer 40 may be disposed on the lower electrode 20. In some implementations, the selection element layer 40 may exhibit different electrical conducting characteristics or states in response to an applied voltage or current with respect to a threshold voltage or current. For example, the selection element layer 40 may exhibit different states of its electrical conductivity when subject to an electric field generated between the lower electrode 20 and the middle electrode 60. For example, a conductive channel may be formed in the selection element layer 40 by an electric field generated between the lower electrode 20 and the middle electrode 60. When the voltage or current associated with the electric field generated between the lower electrode 20 and the middle electrode 60 is less than a threshold voltage or a threshold current, the selection element layer 40 may exhibit non-conductive characteristics or be in a non-electrically conductive state to cut off the electrical path through the selection element layer 40 to the memory element layer 70. When the voltage or current associated with the electric field generated between the lower electrode 20 and the middle electrode 60 is greater than or equal to the threshold voltage or the threshold current, a conductive channel may be formed in the selection element layer 40. Accordingly, the selection element layer 40 can have conductor characteristics. In an embodiment, the selection element layer 40 may include an ion-doped insulating layer. For example, the selection element layer 40 may include at least one of ion-doped silicon oxide, ion-doped titanium oxide, ion-doped aluminum oxide, ion-doped tungsten oxide, ion-doped hafnium oxide, ion-doped tantalum oxide, ion-doped niobium oxide, ion-doped silicon nitride, ion-doped titanium nitride, ion-doped aluminum nitride, ion-doped tungsten nitride, ion-doped hafnium nitride, ion-doped tantalum nitride, ion-doped niobium nitride, ion-doped silicon oxynitride, ion-doped titanium oxynitride, ion-doped aluminum oxynitride, ion-doped tungsten oxynitride, ion-doped hafnium oxynitride, ion-doped tantalum oxynitride, ion-doped niobium oxynitride, or a combination thereof. The ions may include at least one of arsenic (As) or germanium (Ge). For example, the selection element layer 40 may include one of silicon oxides or silicon nitrides doped with at least one of arsenic (As) or germanium (Ge), e.g., at least one of As—SiO₂, Ge—SiO₂, AsGe—SiO₂, As—SiN, Ge—SiN, or AsGe—SiN.

In an embodiment, the selection element layer 40 may include a carbon-based material layer. The selection element layer 40 may further include at least one of hydrogen (H), nitrogen (N), or oxygen (O). The selection element layer 40 may further include doped pentavalent elements. The doped pentavalent elements may include at least one of arsenic (As), phosphorus (P), or antimony (Sb). Accordingly, the selection element layer 40 may include a carbon-based material layer doped with at least one of arsenic (As), phosphorus (P), or antimony (Sb). In an embodiment, the selection element layer may include an arsenic (As)-doped carbon-based material layer. In an embodiment, the selection element layer 40 may be in an amorphous state. In some implementations, the term “carbon-based material layer” can be used to indicate a material layer that includes carbon.

The selection element layer 40 may further include at least one of trivalent elements. For example, the selection element layer 40 may include a compound including carbon atoms and at least one of trivalent elements. The trivalent elements may include at least one of boron (B), aluminum (Al), gallium (Ga), indium (In), or thallium (Tl). In an embodiment, the selection element layer 40 may further include at least one of hydrogen (H), nitrogen (N), or oxygen (O). Accordingly, the selection element layer 40 may include at least one of trivalent elements; at least one of pentavalent elements; at least one of hydrogen (H), nitrogen (N), or oxygen (O); or carbon (C).

The upper carrier tunneling layer 50 may be disposed between the selection element layer 40 and the memory element layer 70. In an embodiment, the upper carrier tunneling layer 50 may include an insulating film. The upper carrier tunneling layer 50 may include an insulating material that is doped with one or more pentavalent elements. For example, the upper carrier tunneling layer 50 may include a silicon-based insulating material doped with at least one of arsenic (As), phosphorus (P), or antimony (Sb). For example, the upper carrier tunneling layer 50 may include at least one of arsenic (As), phosphorus (P), or antimony (Sb); silicon (Si), or at least one of oxygen (O) or nitrogen (N). The upper carrier tunneling layer 50 may further include at least one of boron (B), carbon (C), or hydrogen (H). For example, the upper carrier tunneling layer 50 may include at least one of silicon oxide (SiO2), silicon nitride (SiN), silicon oxy-nitride (SiON), silicon boron oxide (SiBO), silicon boron nitride (SiBN), silicon boron oxynitride (SiBON), silicon carbon oxide (SiCO), silicon carbon nitride (SiCN), silicon carbon oxy-nitride (SiCON), silicon hydro-oxide (SiHO), silicon hydro-nitride (SiHN), silicon hydro-oxy-nitride (SiHON); silicon boron carbon oxide (SiBCO), silicon boron carbon nitride (SiBCN), silicon boron carbon oxy-nitride (SiBCON), silicon boron hydro-oxide (SiBHO), silicon boron hydro-nitride (SiBHN), silicon boron hydro-oxy-nitride (SiBHON), silicon carbon hydro-oxide (SiCHO), silicon carbon hydro-nitride (SiCHN), silicon carbon hydro-nitride (SiCHON), silicon boron carbon oxy-nitride (SiBCHO), silicon boron carbon hydro-nitride (SiBCHN), or silicon boron carbon hydro-oxy-nitride (SiBCOHN) each doped with at least one of arsenic (As), phosphorus (P), or antimony (Sb). In an embodiment, the upper carrier tunneling layer 50 may include at least one of silicon oxide doped with arsenic (As-doped SiO₂), silicon nitride doped with arsenic (As-doped SiN), or silicon oxy-nitride doped with arsenic (As-doped SiON). In some implementations, some of the bonds of the silicon compounds in the upper carrier tunneling layer 50 may be broken. For example, some of the bonds of the silicon compounds may be broken by doping at least one of arsenic (As), phosphorus (P), or antimony (Sb). Alternatively, some of the atoms of the silicon compounds may be substituted with one of arsenic (As), phosphorus (P), or antimony (Sb). When the bonds of the silicon compounds are broken, the electrical resistance of the upper carrier tunneling layer 50 may be significantly reduced. Accordingly, the upper carrier tunneling layer 50 can allow the tunneling of charge carriers (e.g., a current formed by moving charge carriers) in a turned-on state of the selection element layer 40, and can block a leakage current in a turned-off state of the selection element layer 40. The upper carrier tunneling layer 50 may have a very thin thickness to allow the tunneling of charge carriers. In an embodiment, the upper carrier tunneling layer 50 may have a thickness of about 3 Å to about 50 Å.

In an embodiment, the upper carrier tunneling layer 50 may include a layer of a thin high-k insulating metal oxide material. The upper carrier tunneling layer 50 may include a thin metal oxide layer doped with at least one of arsenic (As), phosphorus (P), or antimony (Sb). For example, the upper carrier tunneling layer 50 may include at least one of arsenic (As), phosphorus (P), or antimony (Sb); a metal; and oxygen (O). The metal may include at least one of tungsten (W), titanium (Ti), tantalum (Ta), aluminum (Al), copper (Cu), zinc (Zn), nickel (Ni), cobalt (Co), chromium (Cr), niobium (Nb), molybdenum (Mo), ruthenium (Ru), magnesium (Mg), hafnium (Hf), zirconium (Zr), or other metals. For example, the upper carrier tunneling layer 50 may include at least one of tungsten oxide (WO), titanium oxide (TiO), tantalum oxide (TaO), aluminum oxide (AlO), copper oxide (CuO), zinc oxide (ZnO), nickel oxide (NiO), cobalt oxide (CoO), chromium oxide (CrO), niobium oxide (NbO), molybdenum oxide (MoO), ruthenium oxide (RuO), magnesium oxide (MgO), hafnium oxide (HfO), zirconium oxide (ZrO), or other metal oxides, each doped with at least one of arsenic (As), phosphorus (P), or antimony (Sb). Some of the bonds in the metal oxides contained in the upper carrier tunneling layer 50 may be broken. For example, the bonds in the metal oxides may include metal-oxide bonds. For example, the bonds in the metal oxides can be partially broken by doping at least one of arsenic (As), phosphorus (P), or antimony (Sb). Alternatively, some of the atoms in the metal oxides may be substituted with at least one of arsenic (As), phosphorus (P), or antimony (Sb). As the bonds in the metal oxides are broken, the electrical resistance of the upper carrier tunneling layer 50 may be significantly reduced. Accordingly, the upper carrier tunneling layer 50 can allow the tunneling of a sufficient number of carriers (e.g., passage of a current formed by the charge carriers) in the turned-on state, and can block a leakage current in the turned-off state.

The middle electrode 60 may be disposed on the upper carrier tunneling layer 50. The middle electrode 60 may include a carbon layer. In an embodiment, the middle electrode 60 may include at least one of conductors, e.g., a carbon layer, a metal layer containing carbon, a metal compound layer containing carbon, a metal alloy layer containing carbon, and a metal silicide layer containing carbon. In another embodiment, the middle electrode 60 may include a carbon structure layer such as a graphene layer.

The memory element layer 70 may be disposed on the middle electrode 60. The memory element layer 70 may include a variable resistance layer. For example, the memory element layer 70 may include one of a resistive memory layer, a phase change memory layer, or a magnetic tunnel function (MTJ).

The upper electrode 80 may be disposed on the memory element layer 70. The upper electrode 80 may transmit and/or provide a current passed through the memory element layer 70 to the upper interconnection line 90. The upper electrode 80 may include one of the materials referred for the lower electrode 20.

Referring to FIG. 2B, a memory cell structure MC2 of a semiconductor memory device based on an embodiment of the disclosed technology may include a lower electrode 20, a lower carrier tunneling layer 30, a selection element layer 40, a middle electrode 60, a memory element layer 70, and an upper electrode 80 stacked in the vertical direction Z between a lower interconnection line 10 and an upper interconnection line 90. The lower electrode 20, the lower carrier tunneling layer 30, the selection element layer 40, the middle electrode 60, the memory element layer 70, and the upper electrode 80 may each have one of a pillar shape or a pad shape. The lower carrier tunneling layer 30 may be disposed between the lower electrode 20 and the selection element layer 40. The upper carrier tunneling layer 50 illustrated in FIG. 2A may be omitted. For example, the middle electrode 60 may be disposed directly on the selection element layer 40.

The lower carrier tunneling layer 30 may perform the same function as the upper carrier tunneling layer 50. The lower carrier tunneling layer 30 may include one of the materials referred to as the upper carrier tunneling layer 50. In an embodiment, the lower carrier tunneling layer 30 and the upper carrier tunneling layer 50 may include the same material. In an embodiment, the lower carrier tunneling layer 30 and the upper carrier tunneling layer 50 may include different materials from each other. For example, the lower carrier tunneling layer 30 and the upper carrier tunneling layer 50 may include at least different one of the materials for the upper carrier tunneling layer 50 referred in the description referred to in FIG. 2A. The lower carrier tunneling layer 50 may have a very thin thickness to allow tunneling of carriers. For example, the lower carrier tunneling layer 50 may have a thickness of about 3 Å to 50 Å.

Referring to FIG. 2C, a memory cell structure MC3 of a semiconductor memory device based on an embodiment of the disclosed technology may include a lower electrode 20, a lower carrier tunneling layer 30, a selection element layer 40, an upper carrier tunneling layer 50, a middle electrode 60, a memory element layer 70, and an upper electrode 80 stacked in the vertical direction Z between a lower interconnection line 10 and an upper interconnection line 90. Compared with the memory cell structures MC1 and MC2 illustrated in FIGS. 2A and 2B, the memory cell structure MC3 may include both the lower carrier tunneling layer 30 and the upper carrier tunneling layer 50.

In technical concepts of the disclosed technology, the lower carrier tunneling layer 30 and the upper carrier tunneling layer 50 may each include an insulating material having broken bonds by doping. The insulating material having the broken bonds may have a lowered resistance than a basic resistance. Accordingly, the memory cell structures MC1 to MC3 may have slightly increased electrical resistance, but may be configured to allow a sufficient amount of carriers through in the turned-on state and effectively block a leakage current in the turned-off state.

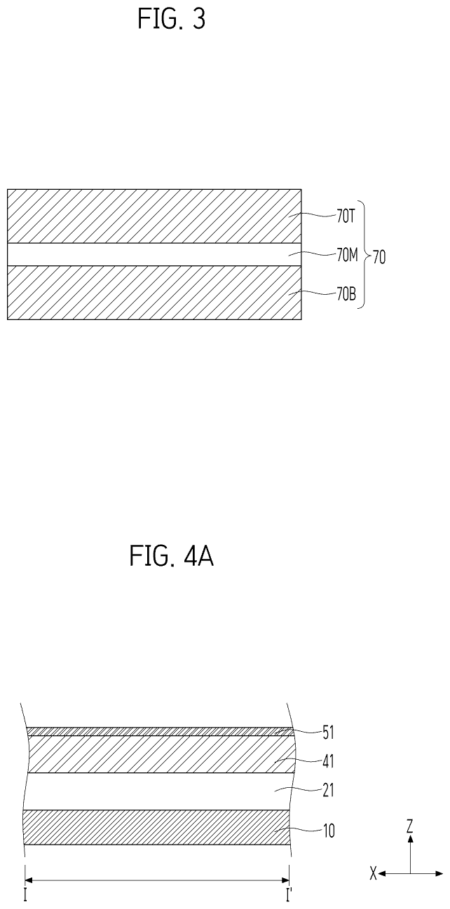

FIG. 3 is a diagram illustrating a memory element layer 70 based on an embodiment of the disclosed technology. Referring to FIG. 3, the memory element layer 70 may include a first layer (lower layer) 70B, a second layer (middle layer) 70M, and a third layer (upper layer) 70T. For example, the memory element layer 70 may include a magnetic tunnel function (MTJ). In some implementations, the term “lower layer” can be used to indicate the first layer (lower layer) is disposed below the second layer (middle layer) and the third layer (upper layer), and the term “upper layer” can be used to indicate the third layer (upper layer) is disposed above the first layer (lower layer) and the second layer (middle layer), and the term “middle layer” can be used to indicate the second layer (middle layer) is disposed above the first layer (lower layer) and below the third layer (upper layer).

The lower layer 70B may be a lower magnetization layer. In an embodiment, the lower layer 70B may include a fixed magnetization layer. The lower layer 70B may have a single layer structure or a multilayer structure including a ferromagnetic material layer. The lower layer 70B may include an alloy or compound including at least two of iron (Fe), nickel (Ni), cobalt (Co), boron (B), platinum (Pt), and palladium (Pd). For example, the lower layer 70B may include at least one of an Fe—Pt alloy, a Fe—Pd alloy, a Co—Pd alloy, a Co—Pt alloy, a Fe—Ni—Pt alloy, a Co—Fe—Pt alloy, a Co—Fe—B alloy, a Co/Pt stack, or a Co/Pd stack.

The middle layer 70M may be disposed between the lower layer 70B and the upper layer 70T. The middle layer 70M may include a tunneling barrier layer. Electrons may tunnel the middle layer 70M by an electric fields generated between the lower electrode 20 and the upper electrode 80. The middle layer 70M may include an insulating metal oxide layer. In an embodiment, the middle layer 70M may include at least one of magnesium oxide (MgO), calcium oxide (CaO), strontium oxide (SrO), titanium oxide (TiO), vanadium oxide (VO), niobium oxide (NbO), aluminum oxide (Al₂O₃), tantalum oxide (Ta₂O₅), ruthenium oxide (RuO₂), and beryllium oxide (Be₂O₃).

The upper layer 70T may be an upper magnetization layer. In an embodiment, the upper layer 70T may include a free magnetization layer. For example, the magnetization direction of the upper layer 70T may be changed by the current. The upper layer 70T may have a single layer structure or a multilayer structure including a ferromagnetic material. The upper layer 70T may include an alloy or a compound including at least two of iron (Fe), nickel (Ni), cobalt (Co), boron (B), platinum (Pt), and palladium (Pd). For example, the upper layer 70T may include at least one of Fe—Pt alloy, Fe—Pd alloy, Co—Pd alloy, Co—Pt alloy, Fe—Ni—Pt alloy, Co—Fe—Pt alloy, Co—Ni—Pt alloy, Co—Fe—B alloy, Co/Pt stack, or Co/Pd stack.

In an embodiment, at least one of the memory structures MC1-MC3 may further include a spacer layer, a magnetization correction layer, and/or a capping layer disposed between the memory element layer 70 and the upper electrode 80. The spacer layer and the capping layer may include a metal layer having excellent etching resistance, e.g., ruthenium (Ru). The magnetization correction layer may include a ferro-magnetic material.

In another embodiment, the lower layer 70B may be the free magnetizing layer, and the upper layer 70T may be the fixed magnetizing layer. For example, positions and/or function of the lower layer 70B and the upper layer 70T may be interchanged.

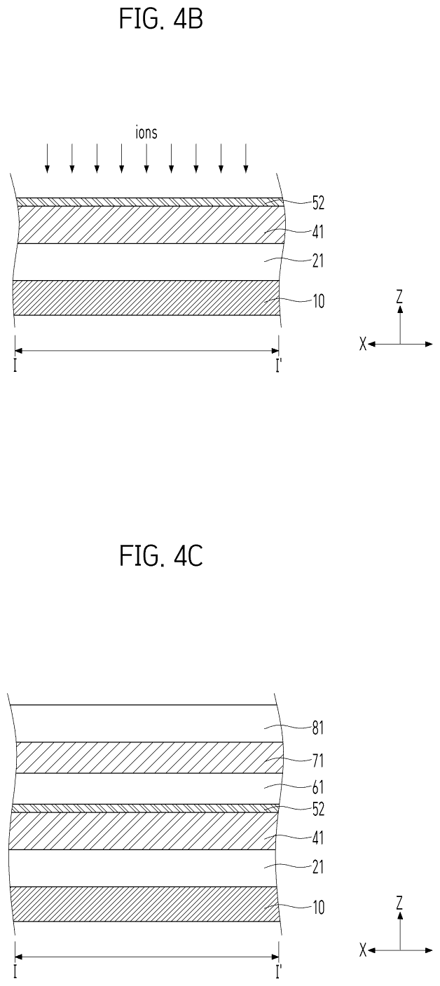

FIGS. 4A to 4D are longitudinal cross-sectional views taken along the line I-I′ of FIG. 1 to describe a method of forming a memory cell structure MC1 based on an embodiment of the disclosed technology. Referring to FIG. 4A, a method of forming the memory cell structure MC1 may include forming a lower electrode material layer 21 on a lower interconnection line 10, forming a selection element material layer 41 on the lower electrode material layer 21, and forming an upper carrier tunneling material layer 51 on the selection element material layer 41.

The lower interconnection line 10 may be formed by forming a metal layer on a base layer (not shown) and performing a patterning process. The lower interconnection line 10 may include a conductor e.g., a metal, a metal silicide, a metal compound, or a metal alloy. The base layer may include a silicon substrate, or an insulating layer such as silicon oxide or silicon nitride.

The lower electrode material layer 21 may be formed by performing a deposition process such as a physical vapor deposition (PVD) process or a chemical vapor deposition (CVD) process. The lower electrode material layer 21 may include a conductor e.g., a metal, a metal silicide, a metal compound, or a metal alloy.

The selection element material layer 41 may be formed by performing a deposition process such as a PVD process or a CVD process, and a plasma doping process or an ion implant process. In an embodiment, the selection element material layer 41 may include at least one of the materials referred with reference to FIG. 2A.

The upper carrier tunneling material layer 51 may be formed by performing a deposition process such as a PVD process or a CVD process. In an embodiment, the upper carrier tunneling material layer 51 may include the silicon-based insulating material layer referred with reference to FIG. 2A. For example, the upper carrier tunneling material layer 51 may include silicon (Si), and may further include at least one of oxygen (O), nitrogen (N), boron (B), carbon (C), or hydrogen (H). In another embodiment, the upper carrier tunneling material layer 51 may include one of the metal oxides referred with reference to FIG. 2A.

Referring to FIG. 4B, the method may further include doping at least one of ions of the pentavalent elements in the upper carrier tunneling material layer 51 by performing an ion doping process. The pentavalent elements may include at least one of arsenic (As), phosphorus (P), or antimony (Sb). The upper carrier tunneling material layer 51 may be modified into an ion-doped upper carrier tunneling material layer 52. In an embodiment, the ion-doped upper carrier tunneling material layer 52 may include an arsenic-doped silicon-based insulating material layer. For example, the upper carrier tunneling material layer 52 may include an arsenic-doped silicon nitride layer or an arsenic-doped silicon oxide layer.

The ion doping process may include a plasma doping process. The ion doping process may include doping at least one of arsenic (As) ions, phosphorus (P) ions, or antimony (Sb) ions into the upper carrier tunneling material layer 51 by performing a plasma doping process with a power of about 1 keV to 3 keV and a dose of about 1E15/cm³ to about 5E15/cm³. By the plasma doping process, the doped ions may diffuse from a surface of the upper carrier tunneling material layer 51 into the upper carrier tunneling material layer 51. Therefore, the upper carrier tunneling material layer 51 may be modified to the ion-doped upper carrier tunneling material layer 52 with only negligible physical damages. Thus, the bonds may be partially broken within the ion-doped upper carrier tunneling material layer 52. Alternatively, some of the materials bonded in the ion-doped upper carrier tunneling material layer 52 may be replaced with doped ions by the ion doping process.

Referring to FIG. 4C, the method may further include forming a middle electrode material layer 61 on the ion-doped upper carrier tunneling material layer 52, forming a memory element material layer 71 on the middle electrode material layer 61, and forming an upper electrode material layer 81 on the memory element material layer 71. The middle electrode material layer 61 may include a carbon-based material layer formed by performing a PVD process or a CVD process. For example, the middle electrode material layer 61 may include at least one of conductors, e.g., a carbon layer, a metal containing carbon, a metal compound containing carbon, a metal alloy containing carbon, or a metal silicide containing carbon. In another embodiment, the middle electrode 61 may include a carbon structure layer such as a graphene layer. The memory element material layer 71 may include a variable resistance layer. The upper electrode material layer 81 may include a conductor, e.g., a metal, a metal silicide, a metal compound, or a metal alloy formed by performing a deposition process such as a PVD process or a CVD process.

Referring to FIG. 4D, the method may further include patterning the upper electrode material layer 81, the memory element material layer 71, the middle electrode material layer 61, the upper carrier tunneling material layer 51, the selection element material layer 41, and the lower electrode material layer 21 by forming a mask pattern M on the upper electrode material layer 81 and performing an etching process using the mask pattern M as an etching mask. The memory cell structure MC1 including a lower electrode 20, a selection element layer 40, an upper carrier tunneling layer 50, a middle electrode 60, a memory element layer 70, and an upper electrode 80 may be formed. The mask pattern M may include at least one of silicon-based insulating materials or at least one of metal oxides. For example, the mask pattern M may include at least one of silicon oxide, silicon nitride, silicon oxynitride, a silicon-based insulating material including at least one of carbon, boron, or hydrogen, metal oxide, metal nitride, metal oxynitride, and other at least one of inorganic insulating materials. In another embodiment, the mask pattern M may include a polymeric organic material, e.g., a photoresist.

Thereafter, the method may further include removing the mask pattern M and forming an upper interconnection line 90 on the upper electrode 80 with reference to FIG. 2A. The upper interconnection line 90 may include a conductor, e.g., a metal, a metal silicide, a metal compound, or a metal alloy.

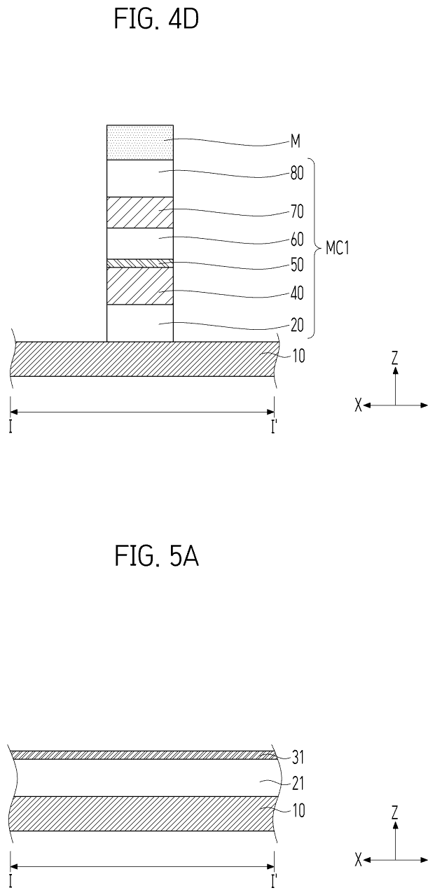

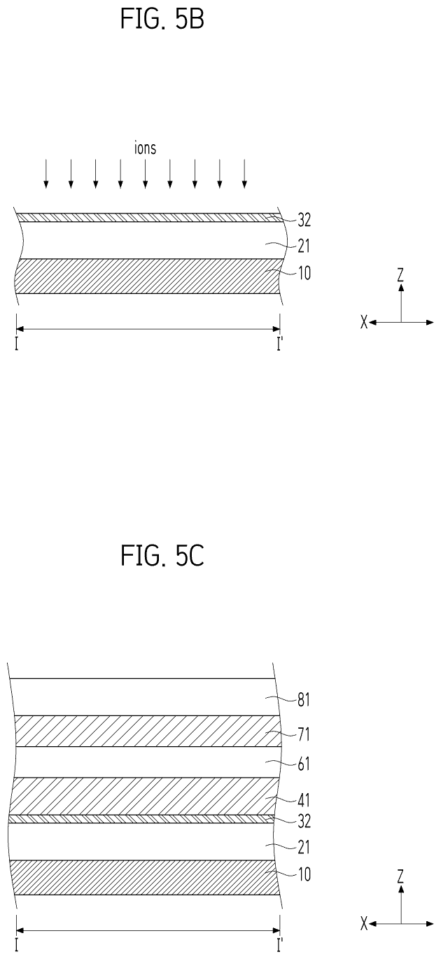

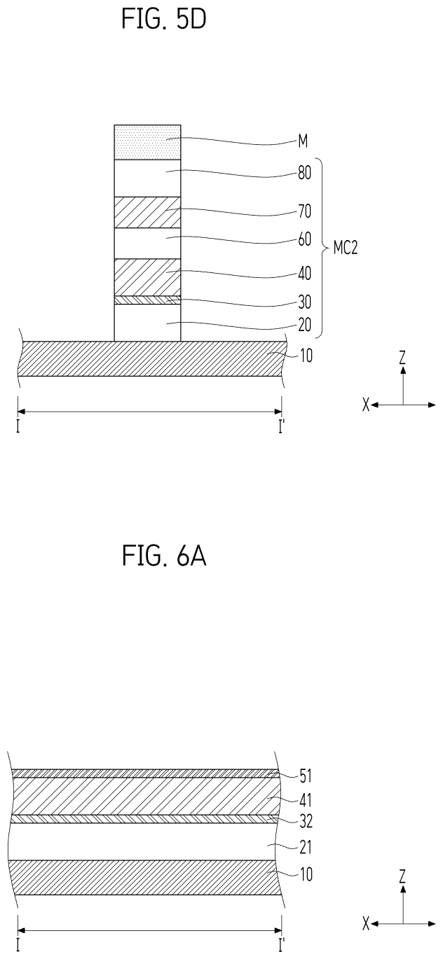

FIGS. 5A to 5D are longitudinal cross-sectional views taken along the line I-I′ of FIG. 1 to describe a method of forming a memory cell structure MC2 based on an embodiment of the disclosed technology. Referring to FIG. 5A, the method of forming the memory cell structure MC2 may include forming a lower electrode material layer 21 on a lower interconnection line 10 and forming a lower carrier tunneling material layer 31 on the lower electrode material layer 21. The lower carrier tunneling material layer 31 may be formed by performing a deposition process such as a PVD process or a CVD process. In an embodiment, the lower carrier tunneling material layer 31 may include a silicon-based material described with reference to FIGS. 2A and 2B. For example, the lower carrier tunneling material layer 31 may include silicon (Si), and may further include at least one of oxygen (O), nitrogen (N), boron (B), carbon (C), or hydrogen (H). In another embodiment, the lower carrier material layer 31 may include at least one of the metal oxides referred with reference to FIGS. 2A and 2B.

Referring to FIG. 5B, the method may further include doping at least one ion of the pentavalent elements in the lower carrier tunneling material layer 31 by performing an ion doping process. The pentavalent elements may include at least one of arsenic (As), phosphorus (P), or antimony (Sb). The lower carrier tunneling material layer 31 may be modified to an ion-doped lower carrier tunneling material layer 32. In an embodiment, the ion-doped lower carrier tunneling material layer 32 may include an arsenic-doped silicon-based insulating material layer. For example, the lower carrier tunneling material layer 32 may include an arsenic-doped silicon nitride layer.

The ion doping process may include a plasma doping process. The ion doping process may include doping at least one of arsenic (As) ions, phosphorus (P) ions, or antimony (Sb) ions into the lower carrier tunneling material layer 31 by performing the plasma doping process with a power of about 1 keV to 3 keV and a dose of about 1E15/cm³ to about 5E15/cm³. During performing the plasma doping process, the doped ions may diffuse from a surface of the lower carrier tunneling material layer 31 into the lower carrier tunneling material layer 31. Therefore, the lower carrier tunneling material layer 31 may be modified to the ion-doped lower carrier tunneling material layer 32 with only negligible physical damages. Thus, the bonds may be partially broken in the ion-doped lower carrier tunneling material layer 32. Alternatively, by the ion doping process, some of the bonded materials in the ion-doped lower carrier tunneling material layer 32 may be replaced with the doped ions.

Referring to FIG. 5C, the method may further include forming a selection element material layer 41 on the ion-doped lower carrier tunneling material layer 32, forming a middle electrode material layer 61 on the selection element material layer 41, forming a memory element material layer 71 on the middle electrode material layer 61, and forming an upper electrode material layer 81 on the memory element material layer 71.

Referring to FIG. 5D, the method may further include patterning the upper electrode material layer 81, the memory element material layer 71, the middle electrode material layer 61, the selection element material layer 41, the lower carrier tunneling material layer 31, and the lower electrode material layer 21 by forming a mask pattern M on the upper electrode material layer 81 and performing an etching process using the mask pattern M as an etching mask. The memory cell structure MC2 including a lower electrode 20, a lower carrier tunneling layer 30, a selection element layer 40, a middle electrode 60, a memory element layer 70, and an upper electrode 80 may be formed. Thereafter, the method may further include removing the mask pattern M and forming the upper interconnection line 90 on the upper electrode 80 with reference to FIG. 2B.

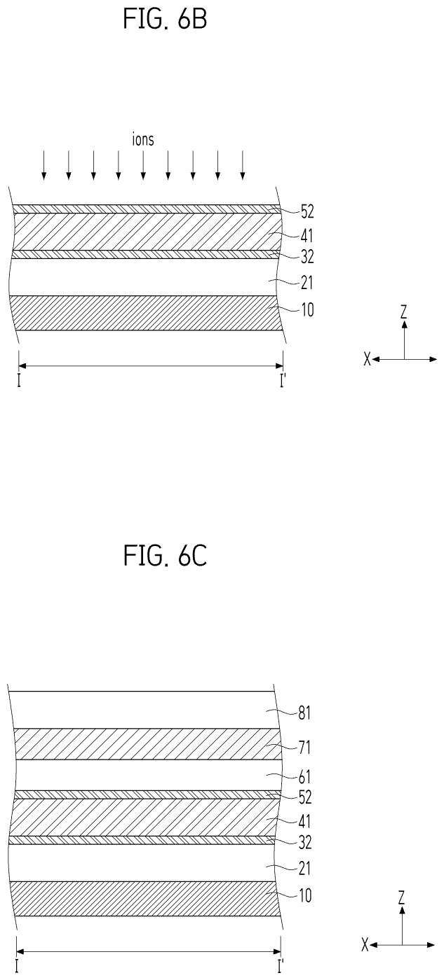

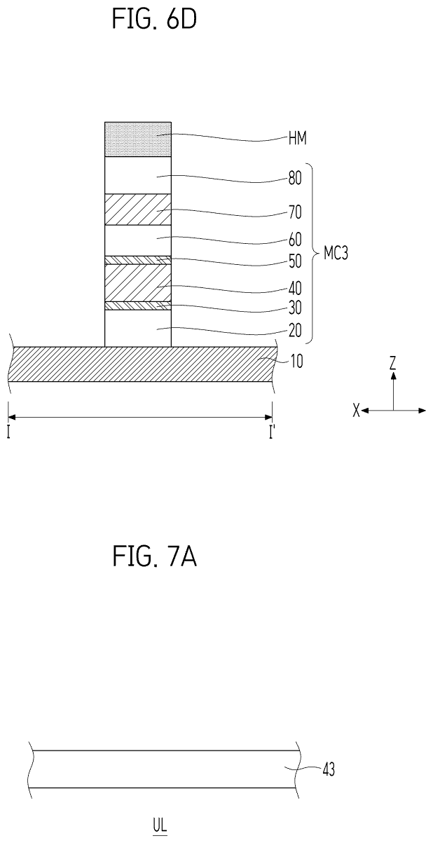

FIGS. 6A to 6D are longitudinal cross-sectional views taken along the line I-I′ of FIG. 1 to describe a method of forming a memory cell structure MC3 based on an embodiment of the disclosed technology. Referring to FIG. 6A, the method of forming the memory cell structure MC3 may include forming a lower electrode material layer 21 on a lower interconnection line 10 by performing the processes described with reference to FIGS. 5A and 5B, forming a lower carrier tunneling material layer 31 on the lower interconnection line 21, forming an ion-doped lower carrier tunneling material layer 32 by doping ions into the lower carrier tunneling material layer 31, forming a selection element material layer 41 on the ion-doped lower carrier tunneling material layer 32, and forming an upper carrier tunneling material layer 52 on the selection element material layer 41.

Referring to FIG. 6B, the method may further include doping at least one of the pentavalent elements into the upper carrier tunneling material layer 51 by performing an ion doping process with reference to FIG. 4B. The upper carrier tunneling material layer 51 may be formed into an ion-doped upper carrier tunneling material layer 52.

Referring to FIG. 6C, the method may further include forming a middle electrode material layer 61 on the ion-doped upper carrier tunneling material layer 52, forming a memory element material layer 71 on the middle electrode material layer 61, and forming an upper electrode material layer 81 on the memory element material layer 71.

Referring to FIG. 6D, the method may further include patterning the upper electrode material layer 81, the memory element material layer 71, the middle electrode material layer 61, the upper carrier tunneling material layer 51, the selection element material layer 41, the lower carrier tunneling material layer 31, and the lower electrode material layer 21 by forming a mask pattern M on the upper electrode material layer 81 and performing an etching process using the mask pattern M as an etching mask. The memory cell structure MC3 including a lower electrode 20, a lower carrier tunneling layer 30, a selection element layer 40, an upper carrier tunneling layer 50, a middle electrode 60, a memory element layer 70, and an upper electrode 80 may be formed. Thereafter, the method may further include removing the hard mask pattern HM and forming an upper interconnection line 90 on the upper electrode 80 with reference to FIG. 2C.

FIGS. 7A to 7B are longitudinal cross-sectional views taken along the line I-I′ of FIG. 1 to describe a method of forming the selection element layer 40 of memory structures MC1 to MC3 based on embodiments of the disclosed technology. Referring to FIG. 7A, a method of forming the selection element layer 40 based on an embodiment of the disclosed technology may include forming a silicon oxide layer 43 on an underlying layer UL with reference to FIG. 4A or FIG. 5C. The underlying layer UL may be one of the lower electrode material layer 21 and the doped lower carrier tunneling material layer 32.

Referring to FIG. 7B, the method may further include doping arsenic (As) or germanium (Ge) into the silicon oxide material layer 43 by performing an ion doping process. The silicon oxide material layer 43 may be modified to an ion-doped silicon oxide material layer 44. The ion-doped silicon oxide material layer 44 may include at least one of an arsenic (As) doped silicon oxide (SiO₂), a germanium (Ge) doped silicon oxide (SiO₂), and a silicon oxide (SiO₂) doped with both arsenic (As) and germanium (Ge). The ion-doped silicon oxide material layer 44 may correspond to the selection element material layer 41 shown in other drawings.

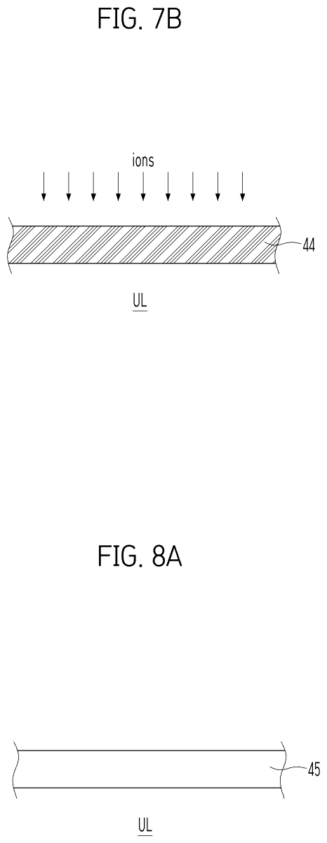

FIGS. 8A and 8B are longitudinal cross-sectional views taken along line the I-I′ of FIG. 1 to describe a method of forming the selection element layer 40 of memory structures MC1 to MC3 based on embodiments of the disclosed technology. Referring to FIG. 8A, a method of forming the selection element layer 40 based on an embodiment of the disclosed technology may include forming a carbon-based material layer 45 on an underlying layer UL. The underlying layer UL may be one of the lower electrode material layer 21 and the doped lower carrier tunneling material layer 32. The carbon-based material layer 45 may include one of an amorphous carbon layer, a nanocrystalline carbon layer, graphite, graphene, diamond-like carbon (DLC), or a carbon nanosheet. The carbon-based material layer 45 may further include at least one of hydrogen (H), nitrogen (N), and oxygen (O).

Referring to FIG. 8B, the method may further include doping at least one of the pentavalent elements in the carbon-base material layer 45 by performing an ion doping process. For example, the pentavalent elements may include at least one of arsenic (As), phosphorus (P), and antimony (Sb). The carbon-based material layer 45 may be modified to the ion-doped carbon-based material layer 46. The ion-doped carbon-based material layer 46 may be at least one of an arsenic (As) doped carbon-based material layer, a phosphorus (P) doped carbon-based material layer, and an antimony (Sb) doped carbon-based material layer. The ion-doped carbon-based material layer 46 may further include at least one of hydrogen (H), nitrogen (N), and oxygen (O). The ion-doped carbon-based material layer 46 may correspond to the selection element material layer 41 shown in other drawings.

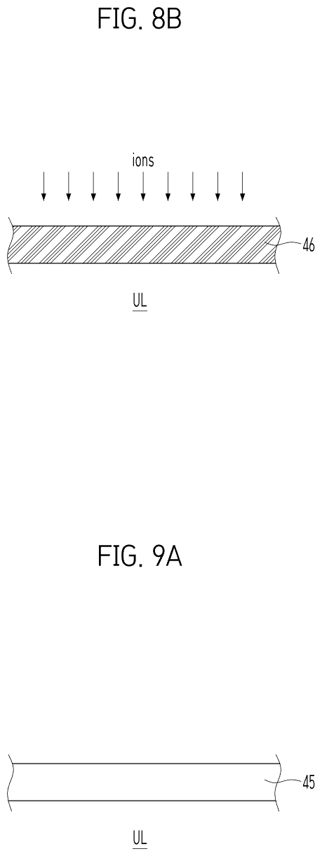

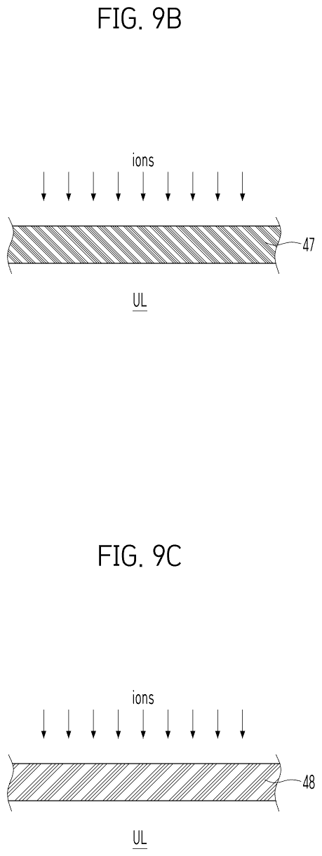

FIGS. 9A to 9C are longitudinal cross-sectional views taken along the line I-I′ of FIG. 1 to describe a method of forming the selection element layer 40 of the memory structures MC1 to MC3 based on some embodiments of the disclosed technology. Referring to FIG. 9A, a method of forming a selection element layer 40 based on an embodiment of the disclosed technology may include forming a carbon-based material layer 45 on an underlying layer UL with reference to FIG. 8A.

Referring to FIG. 9B, the method may further include performing a chemical reaction to diffuse at least one of the elements of the trivalent elements into the carbon-based material layer 45 to induce the chemical reaction and a chemical bond. The trivalent elements may include at least one of boron (B), aluminum (Al), gallium (Ga), indium (In), and thallium (Tl). The carbon-based material layer 45 may be modified to a carbon-based material layer 47 having chemical bonds. The carbon-based material layer 47 having the chemical bonds may be one of a carbon layer having the chemical bonds with boron (B), a carbon layer having the chemical bonds with aluminum (Al), a carbon layer having the chemical bonds with gallium (Ga), a carbon layer having the chemical bonds with indium (In), or a carbon layer having the chemical bonds with thallium (Tl). The carbon-based material layer 47 having the chemical bonds may be thicker than the carbon-based material layer 45. The chemical reaction may include performing a plasma doping process and/or and annealing process at 200° C. to 800° C. For example, the chemical reaction may include performing a plasma doping process under a power of 1 Kev to 5 KeV and a dose of 2E15/cm³ to 2.5E16/cm³. In an embodiment, when boron (B) is doped and diffused into the carbon-based material layer 45, the plasma doping process may be performed using a B₂H₆ plasma or a BF₃ plasma. Hydrogen (H) ions in the B₂H₆ plasma or the BF₃ plasma may form the chemical bonds in the chemically reacted carbon-based material layer 47.

Referring to FIG. 9C, the method may further include doping at least one of the pentavalent elements into the chemically-reacted carbon-based material layer 47 using an ion doping process. For example, the pentavalent elements may include at least one of arsenic (As), phosphorus (P), or antimony (Sb). The chemically-reacted carbon-based material layer 47 may be modified to the chemically-reacted and ion-doped carbon-based material layer 48. The chemically-reacted and ion-doped carbon-based material layer 48 may include at least one of boron (B), aluminum (Al), gallium (Ga), indium (In), or thallium (Tl), and at least one of arsenic (As), phosphorus (P), and antimony (Sb). The chemically-reacted and ion-doped carbon-based material layer 48 may further include at least one of hydrogen (H), nitrogen (N), and oxygen (O). The chemically reacted and ion-doped carbon-based material layer 48 may correspond to the selection element material layer 41 shown in other drawings.

In this way, the disclosed technology can be implemented in some embodiments to provide a semiconductor device including a memory cell that exhibits sufficient carrier tunneling efficiency in a turned-on state and a low leakage current in a turned-off state.

Only a few embodiments and examples are described. Enhancements and variations of the disclosed embodiments and other embodiments can be made based on what is described and illustrated in this patent document.

What is claimed is:

1. A semiconductor device comprising:
a first interconnection line;
a memory cell structure structured disposed over the first interconnection line; and
a second interconnection line disposed over the memory cell structure,
wherein the memory cell structure includes:
a first electrode disposed over the first interconnection line;
a selection element layer disposed over the first electrode;
a first carrier tunneling layer disposed over the selection element layer;
a middle electrode disposed over the first carrier tunneling layer;
a memory element layer disposed over the middle electrode; and
a second electrode disposed over the memory element layer,
wherein the first carrier tunneling layer includes an insulating layer doped with at least one pentavalent element.

2. The semiconductor device of claim 1,
wherein the first carrier tunneling layer includes a silicon-based insulating layer doped with arsenic.

3. The semiconductor device of claim 2,
wherein the silicon-based insulating layer doped with arsenic includes at least one of oxygen or nitrogen.

4. The semiconductor device of claim 3,
wherein the silicon-based insulating layer doped with arsenic further includes at least one of boron, carbon, or hydrogen.

5. The semiconductor device of claim 1,
wherein a thickness of the first carrier tunneling layer is a range of 3 Å to 50 Å.

6. The semiconductor device of claim 1,
wherein the first carrier tunneling layer includes a metal oxide layer doped with arsenic.

7. The semiconductor device of claim 6,
wherein the metal oxide layer includes at least one of a tungsten oxide layer, a titanium oxide layer, a tantalum oxide layer, an aluminum oxide layer, a copper oxide layer, a zinc oxide layer, a nickel oxide layer, a cobalt oxide layer, a chromium oxide layer, a niobium oxide layer, a molybdenum oxide layer, a ruthenium oxide layer, a magnesium oxide layer, a hafnium oxide layer, or a zirconium oxide layer.

8. The semiconductor device of claim 1,
wherein the selection element layer includes a silicon oxide doped with arsenic.

9. The semiconductor device of claim 1,
wherein the selection element layer includes a carbon-based material layer.

10. The semiconductor device of claim 9,
wherein the selection element layer further includes at least one of hydrogen, nitrogen, or oxygen.

11. The semiconductor device of claim 9,
wherein the selection element layer further includes at least one of boron, aluminum, gallium, indium, or thallium.

12. The semiconductor device of claim 9,
wherein the selection element layer further includes at least one of arsenic, phosphorus, or antimony.

13. The semiconductor device of claim 1,
wherein the memory cell structure further includes a second carrier tunneling layer located between the first electrode and the selection element layer.

14. The semiconductor device of claim 1,
wherein the middle electrode includes a carbon-based material layer.

15. A semiconductor device comprising:
a lower interconnection line;
a first electrode disposed over the lower interconnection line;
a selection element layer disposed over the first electrode;
a second electrode disposed over the selection element layer;
a memory element layer disposed over the second electrode;
a third electrode disposed over the memory element layer;
an upper interconnection line disposed on the third electrode; and
a carrier tunneling layer disposed between the first electrode and the selection element layer or between the selection element layer and the second electrode,
wherein the second electrode includes a carbon-based material layer, and
wherein the carrier tunneling layer includes an insulating layer doped with at least one pentavalent element.

16. The semiconductor device of claim 15,
wherein the selection element layer includes a silicon oxide layer doped with arsenic.

17. The semiconductor device of claim 15,
wherein the carbon-based material layer includes:
carbon;
at least one of hydrogen, nitrogen, or oxygen; and
at least one of arsenic, phosphorus, or antimony.

18. The semiconductor device of claim 17,
wherein the carbon-based material layer further includes at least one of boron, aluminum, gallium, indium, or thallium.

19. The semiconductor device of claim 15,
wherein the carrier tunneling layer includes a silicon-based insulating layer doped with arsenic.

20. The semiconductor device of claim 15,
wherein the carrier tunneling layer includes a metal oxide layer doped with arsenic.
